(19) United States
(12) Patent Application Publication
(10) Pub. No.: US 2018/0212004 A1
(43) Pub. Date: Jul. 26, 2018

(54) DISPLAY DEVICE

(71) Applicant: Futaba Corporation, Mobara-shi, Chiba (JP)

(72) Inventors: Yuki HIROTA, Mobara-shi, Chiba (JP); Akihiro NONAKA, Mobara-shi, Chiba (JP); Manabu HIEDA, Mobara-shi, Chiba (JP)

(21) Appl. No.: 15/743,159

(22) PCT Filed: Apr. 20, 2016
(86) PCT No.: PCT/JP2016/062561

§ 371 Date: Jan. 9, 2018

(30) Foreign Application Priority Data
Jul. 10, 2015 (JP) 2015-139090

(51) Int. Cl. H01L 27/32; G09F 9/302; H01L 51/52; H01L 51/50; H01L 51/56

(52) U.S. Cl. CPC H01L 27/3246; G09F 9/302; H01L 51/5225; H01L 2227/323; H01L 51/56; H01L 2251/558; H01L 2251/5338; H01L 51/5012

(57) ABSTRACT

A display device capable of suppressing rapid degradation of a lifespan. The display device (1) includes a light emitting region 2 and a non-light emitting region 3 formed above a substrate (11). The display device (1) includes: a first electrode (13) provided above the substrate (11); a second insulating film (14) that includes an opening (14a) exposing the first electrode (13) of the light emitting region (2) and is formed in the non-light emitting region (3) above the substrate (11); an organic EL layer (15) provided above the first electrode (13) via the opening (14a); and a second electrode (16) provided above the second insulating film (14) and the organic EL layer (15). A plurality of holes (16a) dotted throughout the non-light emitting region (3) are formed in the second electrode (16).

### TECHNICAL FIELD

The present invention relates to a display device.

### BACKGROUND ART

In recent years, a self-luminous type display devices in which an organic electro-luminescence (EL) layer are used as a light emitting layer has been used as a display device. For example, Patent Literature 1 discloses a panel of a so-called passive matrix organic EL display that has an image display array formed by a plurality of light emission portions. In the organic EL display using such a panel, a light emitting layer (an organic EL layer) is interposed between one pair of electrodes and the organic EL layer emits light by applying a voltage to the one pair of electrodes.

### CITATION LIST

### Patent Literature

[Patent Literature 1] Japanese Unexamined Patent Publication No. H8-315981

### SUMMARY OF INVENTION

### Technical Problem

Incidentally, the above-described organic EL layer includes a plurality of low molecular or high molecular organic compounds. The organic compounds may chemically react with a gas including moisture or the like and the chemically reacted organic compounds may have no original function in some cases. In this case, non-uniformity may occur in light generated from the organic EL layer (that is, the organic EL layer does not uniformly emit light) or a portion (a dark spot) that emits no light in the organic EL layer may be formed, and thus a lifespan of the display device including the organic EL layer may rapidly degrade in some cases.

An object of the invention is to provide a display device capable of suppressing rapid degradation of a lifespan.

### Solution to Problem

According to an aspect of the invention, there is provided a display device that includes a light emitting region and a non-light emitting region provided above a substrate. The display device includes: a first electrode provided above the substrate; an insulating film that includes an opening exposing the first electrode of the light emitting region and is provided in the non-light emitting region above the substrate; an organic EL layer provided above the first electrode; and a second electrode provided above the insulating film and the organic EL layer. Holes dotted throughout the non-light emitting region are provided in the second electrode.

In the display device, the holes dotted throughout the non-light emitting region are provided in the second electrode provided above the organic EL layer and the insulating film provided in the non-light emitting region above the substrate. Thus, a gas included in the insulating film is released out of the insulating film via the plurality of holes provided in the second electrode. Therefore, it is possible to prevent chemical reaction of the gas with the organic compound contained in the organic EL layer due to invasion of the gas into the organic EL layer in the light emitting region. Accordingly, it is possible to prevent non-uniformity from occurring in light generated from the organic EL layer and prevent a dark spot from forming in the organic EL layer in the organic EL layer. Thus, it is possible to suppress rapid degradation of a lifespan.

The display device according to the aspect of the invention may further include a protrusion protruding from the insulating film exposed by the hole. A height of the protrusion may be greater than a thickness of the second electrode and an area of a top surface of the protrusion may be greater than an area of a bottom surface of the protrusion. For example, in a case in which the second electrode is provided to cover the light emitting region and the non-light emitting region, the protrusion in the non-light emitting region functions as an eave by setting the height of the protrusion and the areas of the top surface and the bottom surface, as described. Thus, it is possible to reliably form the hole in the second electrode in the non-light emitting region. In addition, it is not necessary to perform patterning or the like when the holes are formed, and thus it is possible to simplify a process of manufacturing the display device.

According to another aspect of the invention, there is provided a display device that includes a light emitting region and a non-light emitting region provided above a substrate. The display device includes: a first electrode provided above the substrate; an insulating film that includes an opening exposing the first electrode of the light emitting region and is provided in the non-light emitting region above the substrate; an organic EL layer provided above the first electrode and the insulating film; and a second electrode provided above the organic EL layer. Holes dotted throughout the non-light emitting region are provided in the second electrode and the organic EL layer.

In the display device, the holes dotted throughout the non-light emitting region are provided in the organic EL layer provided above the first electrode and the insulating film, and provided in the second electrode formed above the organic EL layer. Thus, a gas included in the insulating film is released out of the insulating film via the holes provided in the second electrode and the organic EL layer. Therefore, it is possible to prevent chemical reaction of the gas with the organic compound contained in the organic EL layer due to invasion of the gas into the organic EL layer in the light emitting region. Accordingly, it is possible to prevent non-uniformity from occurring in light generated from the organic EL layer and prevent a dark spot from forming in the organic EL layer. Thus, it is possible to suppress rapid degradation of a lifespan.

In the display device according to the other aspect of the invention may further include a protrusion that protrudes from the insulating film exposed by the hole. A height of the protrusion may be greater than a total thickness of the second electrode and the organic EL layer and an area of a top surface of the protrusion may be greater than an area of a bottom area of the protrusion. For example, in a case in which the second electrode is provided to cover the light emitting region and the non-light emitting region, the protrusion in the non-light emitting region functions as an eave by setting the height of the protrusion and the areas of the top surface and the bottom surface, as described. Thus, it is possible to reliably provide the hole in the second electrode in the non-light emitting region. In addition, it is not necessary to perform patterning or the like when the holes are provided, and thus it is possible to simplify a process of manufacturing the display device.

A distance between the light emitting region and the protrusion may be equal to or greater than 5 μm when viewed in a direction vertical to the substrate. In this case, it is possible to prevent a part of the organic EL layer or the second electrode from not being formed in the light emitting region 2 due to the protrusion as an eave.

A distance between the adjacent holes may be equal to or less than 4000 μm when viewed in a direction vertical to the substrate. In this case, the gas included in the insulating film is appropriately released without remaining in a part of the insulating film.

A distance between the light emitting region and the plurality of holes may be equal to or greater than 5 μm when viewed in a direction vertical to the substrate. In this case, since the organic EL layer in the light emitting region is reliably covered with the second electrode, it is possible to prevent the organic compound contained in the organic EL layer from chemically reacting with a gas in the atmosphere.

The display device described in any one of the foregoing paragraphs may be a segment type organic EL display.

The display device described in any one of the foregoing paragraphs may be an active matrix organic EL display.

### Advantageous Effects of Invention

According to an aspect of the invention, it is possible to provide a display device capable of suppressing rapid degradation of a lifespan.

### BRIEF DESCRIPTION OF DRAWINGS

FIG. 1 is a plan view illustrating a display device according to an embodiment.

FIG. 2 is a schematic sectional view illustrating a part of the display device according to the embodiment.

FIG. 3 is a plan view illustrating a display device according to a comparative example.

FIG. 4 is a schematic sectional view illustrating a part of the display device according to the comparative example.

FIG. 5 is a circuit diagram illustrating a pixel of a display device according to a modification example.

FIG. 6 is a schematic sectional view illustrating a part of the display device according to the modification example.

### DESCRIPTION OF EMBODIMENTS

Hereinafter, preferred embodiments of the invention will be described in detail with reference to the attached drawings. In the following description, the same reference numerals are given to the same elements or elements that have the same functions and the repeated description thereof will be omitted.

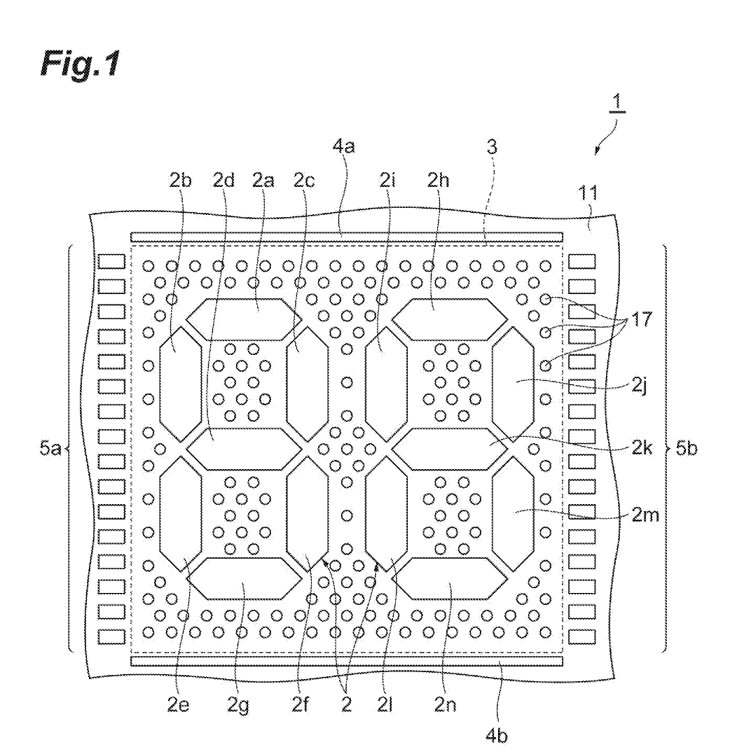

FIG. 1 is a plan view illustrating a display device according to an embodiment. As illustrated in FIG. 1, the display device 1 is a so-called segment type organic EL display that has a light emitting region 2 and a non-light emitting region 3 above a substrate 11. The light emitting region 2 and the non-light emitting region 3 are provided in a region partitioned by one pair of partition walls 4a and 4b extending in parallel and one pair of partition walls 5a and 5b extending in parallel in a direction vertical to the extended direction of the partition walls 4a and 4b, for example, above a main surface of the substrate 11.

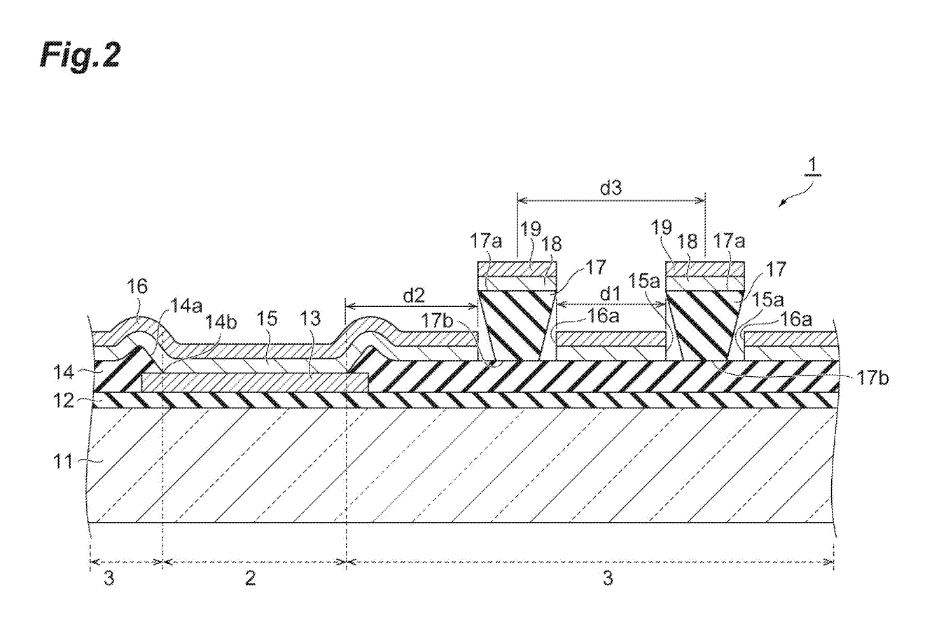

The light emitting region 2 is a region in which light may be generated in a region surrounded by the partition walls 4a, 4b, 5a, and 5b, and is a region in which an opening 14a (see FIG. 2) of a second insulating film 14 to be described below is formed. That is, the light emitting region 2 is a region in which the second insulating film 14 to be described below is not formed, and in which a first electrode 13, an organic EL layer 15, and a second electrode 16 overlap each other (see FIG. 2). The light emitting region 2 is partitioned into regions 2a to 2n. The regions 2a to 2n are connected to different wirings (not illustrated), respectively. The wirings extend in the non-light emitting region 3 and are connected to, for example, terminals of an integrated circuit (not illustrated), respectively. Thus, light emission and non-light emission in the regions 2a to 2n of the light emitting region 2 are independently controlled by the integrated circuit. The display device 1 can display a desired image by arbitrarily emitting light in the regions 2a to 2n. For example, the display device 1 can display an image of “00” by emitting light in the regions other than the regions 2d and 2k in the light emitting region 2.

The non-light emitting region 3 is a region other than the light emitting region 2 in the region surrounded by the partition walls 4a, 4b, 5a, and 5b. The non-light emitting region 3 is a region in which the second insulating film 14 (see FIG. 2) to be described below is formed. A plurality of protrusions 17 are formed to be dotted through the non-light emitting region 3 when viewed in a direction vertical to the substrate 11 (hereinafter simply referred to as a “plan view”) (the details of the protrusions 17 will be described below). The fact that the plurality of protrusions 17 are formed to be dotted through the non-light emission 3 means that, for example, at least one protrusion 17 is formed in 4 mm square in the plan view in the non-light emitting region 3. The protrusion 17 may not be formed in 0.1 mm square or narrower region in the non light emitting region 3.

The partition walls 4a, 4b, 5a, and 5b are portions that partition the display devices 1 from each other when the plurality of display devices 1 are formed above the substrate 11. The partition walls 4a, 4b, 5a, and 5b also function as portions on which a mask is landed when the organic EL layer 15 (see FIG. 2) to be described below is formed by using the mask. In the plan view, each of the partition walls 4a and 4b is one continuous bank and each of the partition walls 5a and 5b is formed by portions which are a plurality of banks. The partition walls 4a, 4b, 5a, and 5b are formed by patterning, for example, an insulating resin (for example, an acrylic resin or polyimide). Each of the partition walls 5a and 5b may be one continuous bank as in the partition walls 4a and 4b.

FIG. 2 is a schematic sectional view illustrating a part of the display device according to the embodiment. As illustrated in FIG. 2, the display device 1 includes the substrate 11, the first insulating film 12, the first electrode 13, the second insulating film 14, the organic EL layer 15, the second electrode 16, and the plurality of protrusions 17. In the light emitting region 2 above the substrate 11 of the display device 1, the first insulating film 12, the first electrode 13, the organic EL layer 15, and the second electrode 16 are formed. In the non-light emitting region 3 above the substrate 11 of the display device 1, the first insulating film 12, the second insulating film 14, the organic EL layer 15, the second electrode 16, and the plurality of protrusions 17 are formed.

The substrate 11 has transparency and has, for example, a rectangular shape in the plan view. As the substrate 11, for example, a glass substrate or any of various plastic substrates is used. The substrate 11 may have flexibility. In this case, for example, a poly ethylene terephthalate film (PET film) is used.

The first insulating film 12 is a transparent film formed to cover one main surface of the substrate 11. As the first insulating film 12, for example, a silicon oxide film, a silicon nitride film, a silicon oxynitride film, or an aluminum oxide film is used. The first insulating film 12 is formed by, for example, a chemical vapor deposition method (CVD method).

The first electrode 13 is an anode and formed above the first insulating film 12 and in the light emitting region 2. The first electrode 13 is formed from a single patterned transparent conductive layer or a plurality of patterned transparent conductive layers. As the material of the transparent conductive layer, for example, an indium tin oxide (ITO) or an indium zinc oxide (IZO) is used. For example, the first electrode 13 is formed by, for example, a physical vapor deposition method (PVD method).

The second insulating film 14 is a film formed above the first insulating film 12 and the first electrode 13. As the second insulating film 14, for example, a silicon oxide film, a silicon nitride film, a silicon oxynitride film, an inorganic film such as an aluminum oxide film, or an organic film such as a novolac resin, an acrylic resin, or polyimide is used. In a case in which the second insulating film 14 is an inorganic film, the second insulating film 14 is formed by, for example, a CVD method. In a case in which the second insulating film 14 is an organic film, the second insulating film 14 is formed by, for example, spin coating. An opening 14a is formed in the second insulating film 14. The opening 14a exposes at least a part of the first electrode 13 from the second insulating film 14. The opening 14a is formed by patterning using, for example, a resist mask. A region demarcated by an edge 14b of the opening 14a above the side of the substrate 11 corresponds to the light emitting region 2. The second insulating film 14 may have transmittance or may have a light-shielding property.

The organic EL layer 15 is a layer in contact with the first electrode 13 in the opening 14a and is formed above the second insulating film 14. The organic EL layer 15 is a layer that contains at least an organic compound (a light-emitting material) that emits light by injecting electrons and holes. The organic compound may be a low molecular compound or may be a high molecular compound. The organic EL layer 15 may include an electron injection layer, an electron transport layer, a hole injection layer, and a hole transport layer in addition to the light-emitting layer that contains the light-emitting material. The light generated by the organic EL layer 15 may be monochromatic light such as red light or blue light or may be white light. In a case in which light generated by the organic EL layer 15 is white light, a plurality of light-emitting layers generating different kinds of light may be included in the organic EL layer 15. The thickness of the organic EL layer 15 is, for example, equal to or greater than 100 nm and equal to or less than 500 nm. The organic EL layer 15 is formed by, for example, a dry method such as a vacuum deposition method or a wet method such as an inkjet method. In the embodiment, the organic EL layer 15 is formed by a dry method. As the light-emitting material, a fluorescent material may be used or a phosphorescent material may be used.

In the organic EL layer 15, a plurality of holes 15a dotted throughout the non-light emitting region 3 are formed. The hole 15a has a circular shape in the plan view. The diameter of the hole 15a is equal to or greater than 10 pin and equal to or less than 300 μm and is, for example, 40 μm. The plurality of holes 15a are formed at substantially regular intervals in the plan view except for some of the holes 15a. Some of the holes 15a are, for example, narrow regions between regions 2e and 2g. A distance d1 between the adjacent holes 15a is equal to or less than 4000 μm, equal to or less than 2000 μm, or equal to or less than 1000 μm in the plan view. In a case in which the distance d1 is greater than 4000 μm, a gas such as moisture included in the second insulating film 14 tends to remain in the second insulating film 14. The remaining gas tends to invade the organic EL layer 15 in the light emitting region 2. In the plan view, a distance d2 between the edge 14b of the opening 14a above the side of the substrate 11 and the hole 15a closest to the edge 14b is equal to or greater than 5 equal to or greater than 50 μm, or equal to or greater than 200 μm. The distance d2 corresponds to a distance between the light emitting region 2 and the hole 15a closest to the light emitting region 2 in the plan view. In a case in which the distance d2 is less than 5 μm, there is a concern that the organic EL layer 15 not being formed in the entire light emitting region 2 and there is a concern that the organic EL layer 15 in the light emitting region 2 not being completely covered with the second electrode 16. In a case in which the organic EL layer 15 in the light emitting region 2 is not covered with the second electrode 16, the organic compound contained in the organic EL layer 15 in the light emitting region 2 may chemically react with a gas in the atmosphere.

The second electrode 16 is a cathode formed above the second insulating film 14 and the organic EL layer 15. The second electrode 16 is formed to be in contact with the organic EL layer 15. The second electrode 16 is configured to include, for example, a single conductive layer or a plurality of conductive layers with light absorptivity or light reflectivity. As a material of the conductive layer (conductive material) of the second electrode 16, for example, alkaline earth metal such as aluminum, silver, magnesium, or calcium is used. The thickness of the second electrode 16 is, for example, equal to or greater than 100 nm and equal to or less than 500 nm. The second electrode 16 is formed by, for example, a PVD method.

In the second electrode 16, a plurality of holes 16a dotted throughout the non-light emitting region 3 are formed. The holes 16a respectively have a circular shape in the plan view. The holes 16a overlap the corresponding holes 15a. Accordingly, a distance between the adjacent holes 16a in the plan view corresponds to the distance d1. A distance between the light emitting region 2 and the hole 16a closest to the light emitting region 2 in the plan view corresponds to the distance d2. The diameter of the hole 16a is equal to or greater than 10 μm and equal to or less than 300 μm and is, for example, 40 μm.

The protrusion 17 is a portion that protrudes from the second insulating film 14 exposed by the holes 15a and 16a. The protrusions 17 are formed before the organic EL layer 15 and the second electrode 16 are formed. Thus, before the protrusions 17 are formed, it is not necessary to pattern the organic EL layer 15 and the second electrode 16. One protrusion 17 is formed to correspond to the holes 15a and 16a. Accordingly, the protrusions 17 are formed at substantially regular intervals except for some of the protrusions 17 as in the holes 15a and 16a. A distance between the centers of the adjacent protrusions 17 (that is, a distance connecting the centers of the adjacent protrusions 17) d3 is changed in accordance with the distance d1 between the adjacent holes 15a or the adjacent holes 16a and with the diameters of the holes 15a and 16a. The distance d3 between the centers of the adjacent protrusions 17 is, for example, equal to or greater than 100 μm and equal to or less than 4000 μm. The protrusions 17 are forming simultaneously with the partition walls 4a, 4b, 5a, and 5b. Therefore, the protrusions 17 are formed of an insulating resin as in the partition walls 4a, 4b, 5a, and 5b.

The protrusion 17 has a top surface 17a that has a substantially circular shape in the plan view. The diameter of the top surface 17a is substantially the same as the diameters of the holes 15a and 16a and the center of the top surface 17a overlaps the centers of the holes 15a and 16a. A bottom surface 17b of the protrusion 17, which is a surface in contact with the second insulating film 14, has a substantially circular shape in the plan view, and the center of the bottom surface 17b overlaps the center of the top surface 17a. The area of the bottom surface 17b is less than the area of the top surface 17a and the diameter of the bottom surface 17b is less than the diameter of the top surface 17a. Accordingly, the protrusion 17 has an inverted frustconical shape and the cross-sectional shape of the protrusion 17 has a substantially inverted trapezoidal shape. In addition, the height of the protrusion 17 is greater than a total thickness of the organic EL layer 15 and the second electrode 16 and is, for example, equal to or greater than 2 μm and equal to or less than 10 μm. In an annular region in which the holes 15a and 16a overlap the top surface 17a and do not overlap the bottom surface 17b, the second insulating film 14 is exposed.

A distance between the light emitting region 2 and the protrusion 17 in the plan view corresponds to the distance d2. In a case in which the distance between the light emitting region 2 and the protrusion 17 is less than the distance d2, the protrusion 17 serves as an eave, and the organic EL layer 15 or the second electrode 16 may not be formed in a part of the light emitting region 2.

An organic layer 18 and a conductive layer 19 are formed above the top surface 17a of the protrusion 17. The organic layer 18 is formed simultaneously with the organic EL layer 15 and is apart from the organic EL layer 15. When the organic EL layer 15 is forming, a part of the organic material that becomes the organic EL layer 15 does not reach above the second insulating film 14 and reaches above the top surface 17a of the protrusion 17, so that the organic layer 18 is formed. Similarly, the conductive layer 19 is formed simultaneously with the second electrode 16 and is apart from the second electrode 16. When the second electrode 16 is formed, a part of the conductive material of the second electrode 16 does not reach above the organic EL layer 15 and reaches above the organic layer 18, so that the conductive layer 19 is formed.

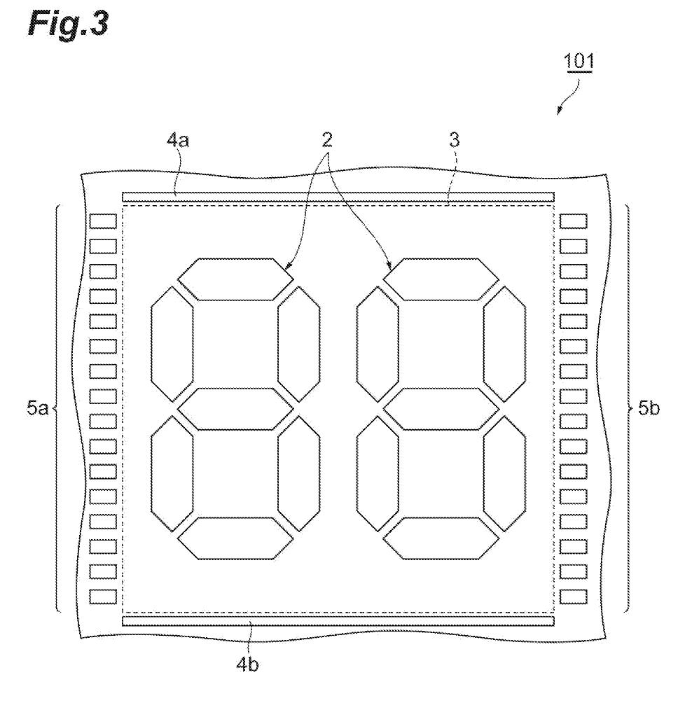

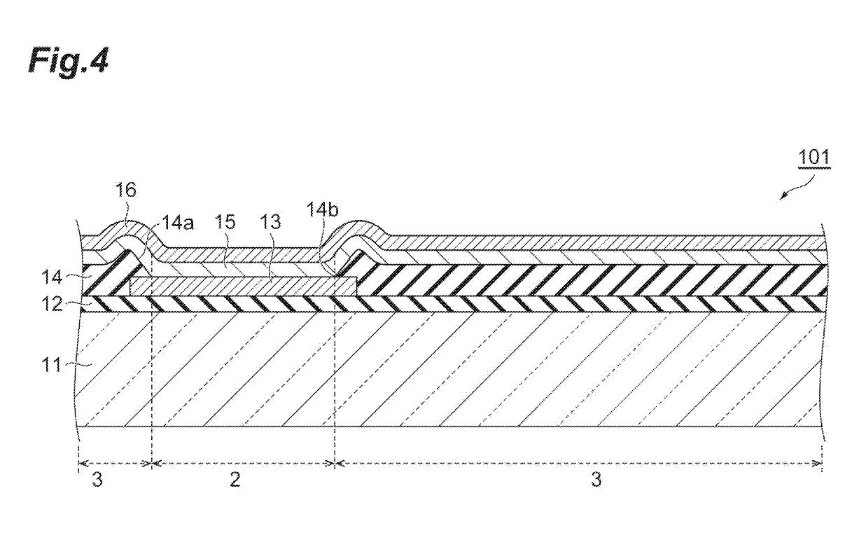

The advantageous effects obtained in the display device 1 according to the above-described embodiment will be described with reference to FIGS. 3 and 4. FIG. 3 is a plan view illustrating a display device according to a comparative example. FIG. 4 is a schematic sectional view illustrating a part of the display device according to the comparative example. As illustrated in FIGS. 3 and 4, a display device 101 according to the comparative example has the same configuration as the display device 1 according to the embodiment except that the holes 15a are not formed in the organic EL layer 15 overlapping the non-light emitting region 3, the holes 16a are not formed in the second electrode 16 overlapping the non-light emitting region 3, and the protrusion 17 is not formed in the non-light emitting region 3. Thus, in the non-light emitting region 3 of the display device 101 according to the comparative example, since the holes 16a are not formed in the second electrode 16, the organic EL layer 15 formed in the light emitting region 2 and the non-light emitting region 3 is covered with the second electrode 16.

Here, when the display device 1 according to the embodiment and the display device 101 according to the comparative example are continuously driven for 500 hours under the conditions of 105° C. in the atmosphere to compare the states to each other, non-uniformity occurs in part of light generated from the light emitting region 2 in the display device 101 according to the comparative example. According to a result of the comparative example, it is considered that the gas included in the second insulating film 14 flows by radiation of heat or ultraviolet light with use of the display device 1 and occurs due to invasion of the gas into the organic EL layer 15 in the light emitting region 2. That is, in the comparative example, it is considered that the organic compound contained in the organic EL layer 15 in the light emitting region 2 chemically reacts with the gas and the performance of the organic EL layer 15 deteriorates, and thus non-uniformity occurs in the part of the light generated from the light emitting region 2.

In the display device 1 according to the embodiment, however, non-uniformity does not occur in light generated from the light emitting region 2 and a dark spot is not confirmed in the light emitting region 2 either. A difference between the result of the comparative example and the result of the embodiment is caused due to the structure of the display device 1 according to the embodiment in which it is difficult to degrade the lifespan of the organic EL layer 15. That is, in the display device 1 according to the embodiment, the holes 16a dotted throughout the non-light emitting region 3 are formed in the second electrode 16 formed above the second insulating film 14 and the organic EL layer 15, the second insulating film 14 and the organic EL layer 15 being above the substrate 11. Additionally, the holes 15a overlapping the holes 16a are formed in the organic EL layer 15. Thus, the gas included in the second insulating film 14 flows with use of the display device 1 and releases out of the second insulating film 14 via the holes 15a formed in the organic EL layer 15 and the holes 16a formed in the second electrode 16. Therefore, the invasion of the gas into the organic EL layer 15 in the light emitting region 2 and the chemical reaction of the gas with the organic compound contained in the organic EL layer 15 are prevented. Accordingly, it is possible to prevent non-uniformity from occurring in the light generated from the organic EL layer 15 and prevent a dark spot from forming in the organic EL layer 15. Thus, it is possible to suppress rapid degradation of the lifespan of the display device 1.

The display device 1 includes the protrusions 17 that protrude from the second insulating film 14 exposed by the holes 16a. The height of the protrusions 17 is greater than the total thickness of the organic EL layer 15 and the second electrode 16, and the area of the top surface 17a is greater than the area of the bottom surface 17b. For example, in a case in which the second electrode 16 is formed to cover the light emitting region 2 and the non-light emitting region 3, the protrusions 17 in the non-light emitting region 3 function as the eaves by setting the height of the protrusions 17 and the areas of the top surface 17a and the bottom surface 17b, as described above. Thus, in the organic EL layer 15 and the second electrode 16 overlapping the non-light emitting region 3, the holes 15a and 16a can be reliably formed around the bottom surfaces 17b of the protrusions 17. Additionally, it is not necessary to perform patterning or the like when the holes 15a and 16a are formed, and thus it is possible to simplify a process of manufacturing the display device 1.

When viewed in the direction vertical to the substrate 11, the distance d2 between the protrusion 17 and the light emitting region 2 (that is, the edge 14b of the opening 14a above the side of the substrate 11) is equal to or greater than 5 μm. In this case, it is possible to prevent a part of the organic EL layer 15 or the second electrode 16 from not being formed in the light emitting region 2 due to the protrusion as an cave.

When viewed in the direction vertical to the substrate 11, the distance d1 between the adjacent holes 16a is equal to or less than 4000 μm. In this case, the gas included in the second insulating film 14 is appropriately released without remaining in a part of the second insulating film 14.

When viewed in the direction vertical to the substrate 11, the distance d2 between the hole 16a and the light emitting region 2 (that is, the edge 14b of the opening 14a above the side of the substrate 11) is equal to or greater than 5 μm. In this case, since the organic EL layer 15 in the light emitting region 2 is reliably covered with the second electrode 16, the organic compound contained in the organic EL layer 15 can be prevented from chemically reacting with a gas in the atmosphere.

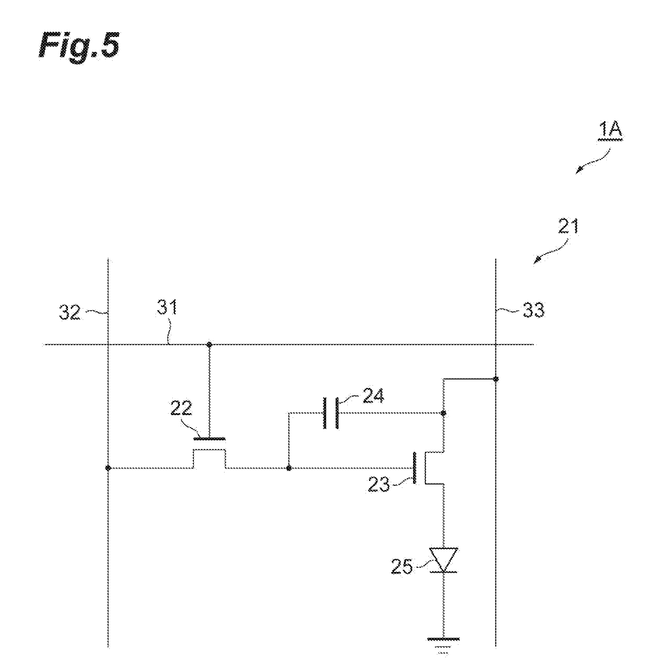

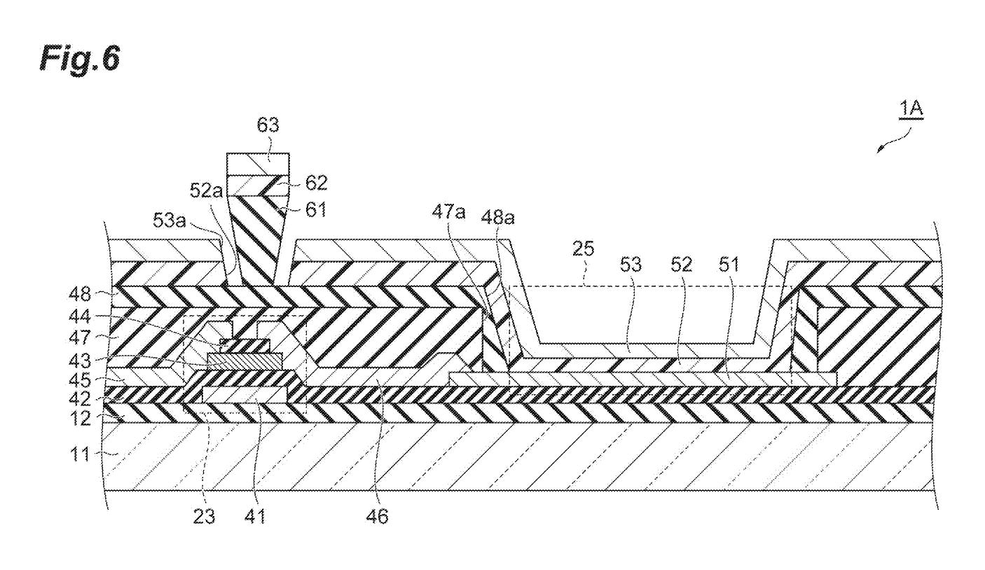

Next, a display device according to a modification example of the embodiment will be described with reference to FIGS. 5 and 6. FIG. 5 is a schematic circuit diagram illustrating a pixel of the display device according to the modification example. As illustrated in FIG. 5, a display device 1A includes a pixel 21. The pixel 21 includes a first transistor 22, a second transistor 23, a capacitor 24, and a light-emitting element 25 including an organic EL layer. In the display device 1A, the plurality of pixels 21 are disposed in a matrix form. Accordingly, the display device 1A according to the modification example is an active matrix organic EL display.

In the pixel 21, a gate of the first transistor 22 is connected to a first signal line 31, one of a source and a drain of the first transistor 22 is connected to a second signal line 32, and the other of the source and the drain of the first transistor 22 is connected to a gate of the second transistor 23 and one electrode of the capacitor 24. One of a source and a drain of the second transistor 23 is connected to a power line 33 and the other electrode of the capacitor 24, and the other of the source and the drain of the second transistor 23 is connected to one electrode of the light-emitting element 25. The other electrode of the light-emitting element 25 is grounded.

Next, an operation of the pixel 21 will be described in brief. When a first signal is input to the first signal line 31, the first transistor 22 is turned on. At this time, when a second signal input from the second signal line 32 is input to the gate of the second transistor 23 via the first transistor 22, charge is accumulated in the gate of the second transistor 23 and the capacitor 24. In accordance with the amount of accumulated charge, power to be supplied from the power line 33 via the second transistor 23 to the light-emitting element 25 is changed. Thus, whether the light-emitting element 25 emits light and the degree of emission of light from the light-emitting element 25 are controlled.

FIG. 6 is a schematic sectional view illustrating a part of the display device according to the modification example. As illustrated in FIG. 6, the second transistor 23 and the light-emitting element 25 are formed above the first insulating film 12.

The second transistor 23 is a so-called bottom gate type field effect transistor and is a p-type transistor in the embodiment. The second transistor 23 includes a gate 41, an interlayer insulating film 42, a semiconductor layer 43 functioning as a channel, a channel stop layer 44, a drain 45, and a source 46. The source 46 of the second transistor 23 is connected to the light-emitting element 25. A flattened film 47 formed of an insulating resin is formed above the second transistor 23. An opening 47a is formed in a part of the flattened film 47. An insulating film 48 is formed above the flattened film 47. The insulating film 48 is, for example, an inorganic insulating film such as a silicon nitride film and is formed to cover the flattened film 47. In the insulating film 48, an opening 48a is formed in at least a part of a portion overlapping the opening 47a.

The light-emitting element 25 includes a first electrode 51 formed in the interlayer insulating film 42, an organic EL layer 52 formed to be in contact with the insulating film 48 and the first electrode 51, and a second electrode 53 formed to be in contact with the organic EL layer 52. As indicated by a dotted line of FIG. 6, the light-emitting element 25 corresponds to a portion which is in the opening 48a and in which the first electrode 51, the organic EL layer 52, and the second electrode 53 overlap each other. In the display device 1A, the portion in which the light-emitting element 25 is formed corresponds to the light emitting region 2 according to the embodiment.

The first electrode 51 is exposed from the flattened film 47 and the insulating film 48 by the openings 47a and 48a and is formed of the same material as the first electrode 13 according to the embodiment. The organic EL layer 52 is formed of the same material as the organic EL layer 15 according to the embodiment. The organic EL layer 52 is formed not only above the first electrode 51 but is also formed to cover the insulating film 48 unlike the foregoing embodiment. The second electrode 53 is formed of the same material as the second electrode 16 according to the embodiment.

A protrusion 61 is formed above the second transistor 23 and the insulating film 48. The protrusion 61 is formed like the protrusion 17 according to the foregoing embodiment. Therefore, the protrusion 61 has a substantially inverted trapezoidal shape on its cross section and is formed before the organic EL layer 52 is formed. The protrusion 61 is formed before the organic EL layer 52, and thus a hole 52a of the organic EL layer 52 and a hole 53a of the second electrode 53 are formed. The holes 52a and 53a expose a part of the insulating film 48 as in the foregoing embodiment.

In the display device 1A having the above-described configuration according to the modification example, the protrusion 61 is formed to appropriately release a gas included in the insulating film 48 in contact with the organic EL layer 52. Thus, as in the foregoing embodiment, it is possible to prevent non-uniformity from occurring in light generated from the organic EL layer 52 in the light-emitting element 25 and prevent a dark spot from forming in the organic EL layer 52 in the light-emitting element 25. Thus, it is possible to suppress rapid degradation of the lifespan of the display device 1.

The display device according to the invention is not limited to the above-described embodiment and modification example, but various modifications can be made. For example, the invention may be applied not only to the above-described organic EL display but also to other organic EL displays.

In the foregoing embodiment and modification example, the first electrode is the anode and the second electrode is the cathode, but the first electrode may be a cathode and the second electrode may be an anode. In this case, the display device may be top emission type organic EL display. In the modification example, in a case in which the first electrode is a cathode, the second transistor is preferably an n-type transistor.

In the foregoing embodiment and modification example, the shapes of the protrusion and the hole are circular in the plan view, but the invention is not particularly limited thereto. For example, the shapes of the protrusion and the hole may be substantially rectangular, substantially polygonal, or ellipsoidal. The protrusion may be formed, for example, in a stripe form in the plan view. In the foregoing embodiment and modification example, no protrusion may be formed.

In the foregoing embodiment and modification example, an interval between the adjacent protrusions (that is, an interval between the holes) may be changed in accordance with the position of the non-light emitting region 3. For example, in the non-light emitting region 3 which is near the light emitting region 2, the interval between the protrusions may be enlarged. In the non-light emitting region 3 which is not near the light emitting region 2, the interval between the protrusions may be shortened. That is, portions in which the density of the protrusions (or the holes) in the non-light emitting region 3 is high or low may be formed.

In the foregoing embodiment and modification example, the organic EL layer is not patterned, but the invention is not limited thereto. That is, for example, the organic EL layer may be patterned to be formed only in the light emitting region or inside the light-emitting element. In this case, for example, the organic EL layer is patterned to be formed using a mask. When the organic EL layer is formed using a mask, the partition walls and the protrusions may be portions on which the mask is formed. In the foregoing embodiment, in a case in which the organic EL layer is not formed in the non-light emitting region, the height of the protrusion formed above the second insulating film may be greater than the thickness of the second electrode.

In the foregoing embodiment, the diameter of the hole of the organic EL layer and the diameter of the hole of the second electrode may be different from each other. That is, the diameter of the hole of the organic EL layer may be greater or smaller than the diameter of the hole of the second electrode.

In the foregoing modification example, the protrusion is formed to overlap the second transistor, but the invention is not limited thereto. That is, the protrusion may be formed in the non-light emitting region which does not overlap the second transistor.

### REFERENCE SIGNS LIST

1, 1A, 101 display device
2 light emitting region
3 non-light emitting region
11 substrate
12 first insulating film
13, 51 first electrode
14 second insulating film
14a opening
15, 52 organic EL layer
16, 53 second electrode
16a hole
17, 61 protrusion
17a top surface
17b bottom surface
21 pixel
22 first transistor
23 second transistor
25 light-emitting element
48 insulating film
48a opening
d1, d2 distance

1. A display device comprising:
a substrate above which a light emitting region and a non-light emitting region are provided;
a first electrode above the substrate;
an insulating film including an opening exposing the first electrode in the light emitting region, the insulating film being provided in the non-light emitting region;
an organic EL layer above the first electrode; and
a second electrode above the insulating film and the organic EL layer,
wherein holes dotted throughout the non-light emitting region are provided in the second electrode.

2. The display device according to claim 1, further comprising a protrusion protruding from the insulating film exposed by the hole,
wherein a height of the protrusion is greater than a thickness of the second electrode and an area of a top surface of the protrusion is greater than an area of a bottom surface of the protrusion.

3. A display device comprising:
a substrate above which a light emitting region and a non-light emitting region are provided;
a first electrode above the substrate;
an insulating film including an opening exposing the first electrode in the light emitting region, the insulating film being provided in the non-light emitting region;
an organic EL layer above the first electrode and the insulating film; and
a second electrode above the organic EL layer,
wherein holes dotted throughout the non-light emitting region are provided in the second electrode and the organic EL layer.

4. The display device according to claim 3, further comprising a protrusion protruding from the insulating film exposed by the hole,
wherein a height of the protrusion is greater than a total thickness of the second electrode and the organic EL layer and an area of a top surface of the protrusion is greater than an area of a bottom surface of the protrusion.

5. The display device according to claim 2,
wherein a distance between the light emitting region and the protrusion is equal to or greater than 5 μm in a plan view.

6. The display device according to claim 1,
wherein a distance between the adjacent holes is equal to or less than 4000 μm in a plan view.

7. The display device according to claim 1,
wherein a distance between the light emitting region and the holes is equal to or greater than 5 μm in a plan view.

8. The display device according to claim 1,
wherein the display device is a segment type organic EL display.

9. The display device according to claim 1,
wherein the display device is an active matrix organic EL display.

10. The display device according to claim 8, further comprising partition walls above the substrate,
wherein the light emitting region and the non-light emitting region are surrounded by the partition walls.

11. The display device according to claim 10,
wherein the partition walls includes:
a pair of first partition walls extended in parallel with a first direction; and
a pair of second partition walls extended in parallel with a second direction, the second direction being perpendicular to the first direction,
wherein each of the first partition walls includes one continuous bank, and
wherein each of the first partition walls includes a plurality of banks.

12. The display device according to claim 4,
wherein a distance between the light emitting region and the protrusion is equal to or greater than 5 μm in a plan view.

13. The display device according to claim 3,
wherein a distance between the adjacent holes is equal to or less than 4000 μm in a plan view.

14. The display device according to claim 3,
wherein a distance between the light emitting region and the holes is equal to or greater than 5 μm in a plan view.

15. The display device according to claim 3,
wherein the display device is a segment type organic EL display.

16. The display device according to claim 3,
wherein the display device is an active matrix organic EL display.

17. The display device according to claim 15, further comprising partition walls above the substrate,
wherein the light emitting region and the non-light emitting region are surrounded by the partition walls.

18. The display device according to claim 17,
wherein the partition walls includes:
a pair of first partition walls extended in parallel with a first direction; and
a pair of second partition walls extended in parallel with a second direction, the second direction being perpendicular to the first direction,
wherein each of the first partition walls includes one continuous bank, and
wherein each of the first partition walls includes a plurality of banks.
